(19) United States
(12) Patent Application Publication
(10) Pub. No.: US 2026/0230074 A1
(43) Pub. Date: Aug. 6, 2026

(54) LEAKAGE REDUCTION AND BIASING CIRCUITS

(71) Applicant: Google LLC, Mountain View, CA (US)

(72) Inventors: Tong Zhang, Sunnyvale, CA (US); Andrew Abo, San Carlos, CA (US); Johan Peter Vanderhaegen, Cupertino, CA (US)

(21) Appl. No.: 19/149,609

(22) PCT Filed: Jan. 20, 2023
(86) PCT No.: PCT/US2023/011239

§ 371 Date: Jul. 21, 2025

(51) Int. Cl. H03K 19/00; H03K 17/30

(52) U.S. Cl. CPC H03K 19/0013; H03K 17/302; H03K 2217/0036

(57) ABSTRACT

A logic circuit (900) includes a power source (Vdd), a biasing circuit (910), a digital cell (904), a first p-channel metal oxide semiconductor (PMOS) (902) electrically connected between the power source and the digital cell, a second PMOS (906) electrically connected between the power source and a first input (908, INP) of the biasing circuit, and a third PMOS (912) electrically connected between the power source and a second input (914, INM) of the biasing circuit, wherein the digital cell is connected to a common mode voltage (908, virtual Vdd) of the biasing circuit, such that the common mode voltage of the biasing circuit is substantially equal to a voltage (virtual Vdd) received by the digital cell.

### BACKGROUND

Ambient sensing modes are prevalent in many digital logic systems. However, power leakage is significant when logic systems are in ambient sensing modes. For example, in some uses, up to 40% of power usage can occur while a digital logic system is in an idle state, e.g., an ambient sensing mode. In some cases, the logic systems can be in idle states most of the time, e.g., 90% of the time. Power leakage can also occur while the logic system is not in the idle state.

### SUMMARY

This specification describes methods and systems for reducing the power leakage in digital logic systems. For example, power leakage can be reduced using a biasing circuit as described herein. Additionally, the methods and systems described herein can reduce on-resistance of a header switch. Reducing the on-resistance can reduce power loss while the circuit is not in an idle state. Additionally, less area can be used for the same resistance requirements in the circuit.

Particular embodiments of the subject matter described in this specification can be implemented so as to realize one or more of the following advantages.

The described methods and systems create circuits with reduced power loss, both when the circuit is in an idle state and when the circuit is not in an idle state. For example, the switches described can be implemented for low-power and low-leakage applications to further reduce device leakage. Certain voltages can be used to bias the gate of a metal oxide semiconductor field effect transistor (MOSFET), which further reduces power leakage. For example, including both a header and a bottom switch significantly reduces power leakage in the idle state. Additionally, using a biasing voltage to super turn on a switch can reduce the area required by the switch. Additionally, the described methods and systems can be implemented for a low cost and can be applied in a variety of applications. Advantageous biasing circuits provide an accurate replica of the actual circuit, e.g., to minimize leakage over process, voltage, and temperature (PVT) variations.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 is a diagram of a p-channel metal oxide semiconductor PMOS.

FIG. 2 is a plot illustrating applied voltage vs. current across a (PMOS).

FIG. 3 is a diagram of a n-channel metal oxide semiconductor (NMOS).

FIG. 4A is a diagram of a circuit with two PMOS's.

FIG. 4B is a diagram of a circuit with two NMOS's.

FIG. 5 is a diagram of a circuit with a PMOS and an NMOS.

FIG. 6 is a plot illustrating applied voltages vs. currents across PMOS's that are connected to different circuits.

FIG. 7 is another plot illustrating applied voltage vs. current across a PMOS.

FIG. 8 is another plot illustrating applied voltages vs. current across PMOS's with different load voltages.

FIG. 9 is a diagram of an exemplary biasing circuit.

FIG. 10 is a diagram of another exemplary biasing circuit.

Like reference numbers and designations in the various drawings indicate like elements.

### DETAILED DESCRIPTION

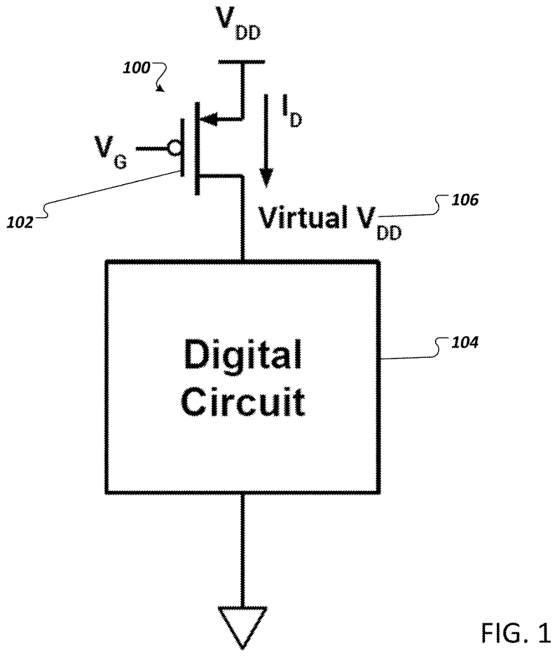

FIG. 1 is a diagram of a p-channel metal oxide semiconductor (PMOS) 100. In general, a PMOS uses metal oxide semiconductor field effect transistors (MOSFETs) to implement logic gates and other digital circuits. The PMOS includes a gate 102 that receives a biasing voltage V_{G} to change the resistance of the PMOS. Applying no biasing voltage to the gate 102 allows a current I_{D} to pass through the PMOS, e.g., “turn on” the PMOS. Applying a positive biasing voltage V_{G}, e.g., that exceeds a threshold value, to the gate 102 increases the resistance of the PMOS 100 such that current does not pass through the PMOS 100, e.g., “cut off” the PMOS 100. The threshold value can be determined by the digital circuit 104. For example, the threshold value to cut off the PMOS 100 can be equivalent to the input voltage V_{DD} of the PMOS 100. The input voltage V_{DD} is a positive supply voltage. In other implementations, the threshold value can be a different value than the input voltage V_{DD}. For example, the threshold value can be determined such that a desired amount of current, e.g., a low amount of current, can pass through the PMOS 100, as discussed below. The threshold value can be determined to reduce the current that can pass through the PMOS 100, e.g., to reduce power leakage. The PMOS 100 outputs a virtual V_{DD} 106 that is received by the digital circuit 102. In some implementations, the virtual V_{DD} 106 can be similar to the input value V_{DD} of the PMOS 100, e.g., if the PMOS 100 has virtually no resistance. In real circuits, the virtual V_{DD} 106 is lesser than the input value V_{D}, e.g., due to physical restrictions.

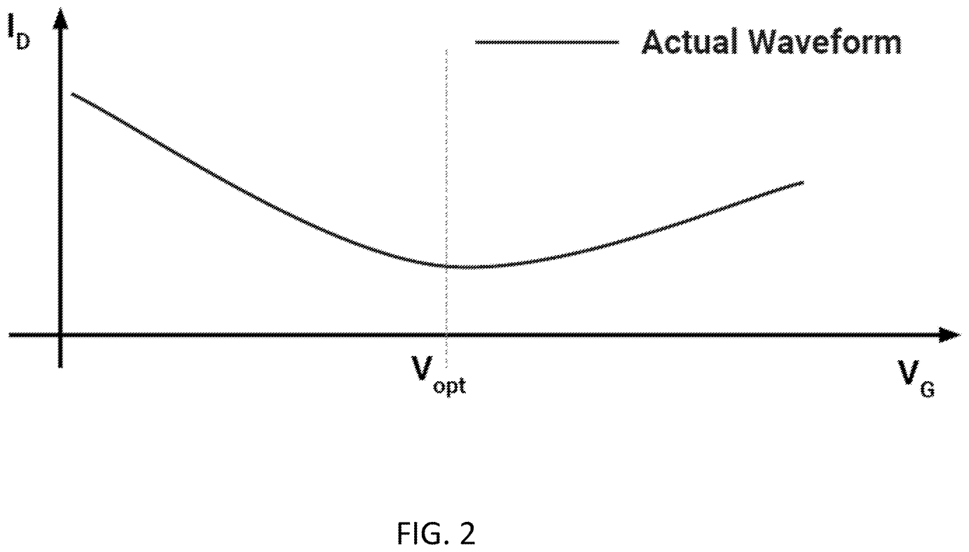

FIG. 2 is a plot illustrating an applied biasing voltage vs. a current across a PMOS. The applied biasing voltage is applied to a gate of a PMOS, e.g., the gate 102 of the PMOS 100 of FIG. 1. As illustrated, the current I_{D} across the PMOS changes depending on the applied biasing voltage. Due to the curved shape of the waveform, there is a certain biasing voltage Vₒₚₜ that allows the least current I_{D} to flow across the PMOS. The current I_{D} may not reach zero, e.g., due to physical restrictions. Applying the biasing voltage Vₒₚₜ when cutting off a PMOS can reduce the power leakage, e.g., by allowing the least amount of current I_{D} to flow through the PMOS. Applying a biasing voltage greater than V_{DD}, e.g., applying the biasing voltage Vₒₚₜ, can lower the power leakage significantly, e.g., creating a “super cut-off.”

Other biasing voltages can be applied to the gate of a PMOS to allow desired amounts of current to flow through the PMOS. For example, along with a super cut-off threshold, the PMOS can have a “super turn on” threshold that significantly lowers the resistance of the PMOS, providing a lower power loss through the switch. This means that a lower supply can be used, creating a more power efficient circuit. Also, a smaller switch can be used, reducing the area taken up by the switch. Revisiting FIG. 1, applying no biasing voltage to the gate 102 allows a current I_{D} to pass through the PMOS, e.g., turning on the PMOS. However, applying a negative biasing voltage to the gate 102 lowers the resistance of the PMOS even further, allowing a larger amount of current to flow through the PMOS, e.g., super turning on the PMOS. A desired negative biasing voltage can be determined to provide power and area efficiency with the PMOS. For example, the desired negative biasing voltage can be determined in a manner similar to determining the biasing voltage Vₒₚₜ that allows the least current I_{D} to flow through the PMOS.

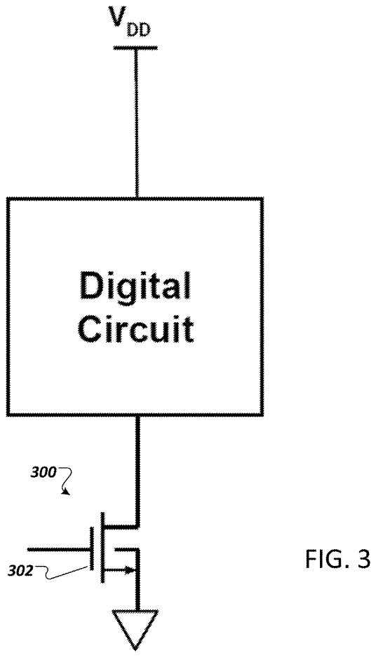

FIG. 3 is a diagram of an n-channel metal oxide semiconductor (NMOS) 300. In general, an NMOS uses MOSFETs to implement logic gates and other digital circuits, e.g., similar to a PMOS. The NMOS includes a gate 302 that can receive a biasing voltage V_{G} to change the resistance of the PMOS. Unlike a PMOS, applying no biasing voltage, or a biasing voltage below a threshold value, to the gate 302 increases the resistance of the NMOS 300 such that current does not pass through the NMOS 300, e.g., cutting off the NMOS 300. Applying a positive biasing voltage, e.g., equal to the input voltage V_{DD} of the circuit, to the NMOS 300 allows current I_{D} to pass through the NMOS, e.g., turning on the NMOS. In this sense, the NMOS works in an opposite manner from the PMOS.

Similarly to the PMOS, the threshold value to cut off the NMOS 300 can be determined such that a desired amount of current, e.g., a low amount of current, can pass through the NMOS 300. The threshold value can be determined to reduce the current that can pass through the NMOS 300, e.g., to reduce power leakage. Similar to a PMOS, there is a certain biasing voltage Vₒₚₜ that allows the least current I_{D} to flow across the NMOS. The current I_{D} may not reach zero, e.g., due to physical restrictions. In the case of an NMOS, the biasing voltage Vₒₚₜ is negative. Applying the negative biasing voltage −Vₒₚₜ when cutting off an NMOS can reduce the power leakage, e.g., by allowing the least amount of current I_{D} to flow through the NMOS. Applying a biasing voltage lower than zero, e.g., applying the negative biasing voltage −Vₒₚₜ, can lower the power leakage significantly, e.g., creating a super cut-off.

Other biasing voltages can be applied to the gate of the NMOS to allow desired amounts of current to flow through the NMOS. For example, similar to a PMOS, the NMOS can have a super turn on threshold that significantly lowers the resistance of the NMOS. As discussed above, applying a positive biasing voltage, e.g., a voltage equal to the input voltage V_{DD} of the circuit, to the gate 302 allows a current I_{D} to pass through the NMOS, e.g., turning on the NMOS. Applying a greater positive biasing voltage, e.g., a voltage greater than the input voltage V_{DD} of the circuit, to the gate 302 lowers the resistance of the NMOS even further, to provide a power efficient and area efficient NMOS, e.g., super turning on the NMOS. A desired positive biasing voltage can be determined to allow the most current I_{D} to flow across the NMOS. For example, the desired positive biasing voltage can be determined in a manner similar to determining the biasing voltage Vₒₚₜ that allows the least current I_{D} to flow through the NMOS.

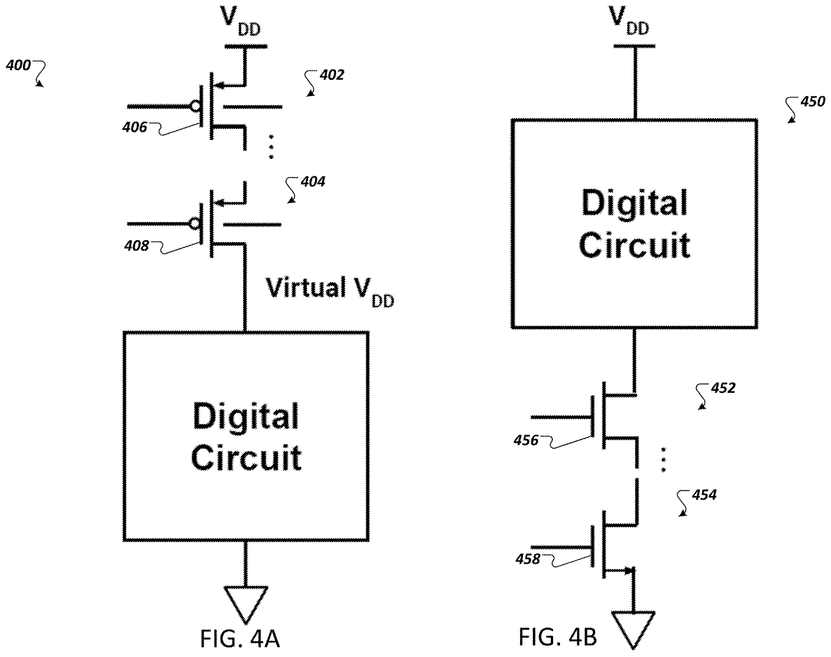

Multiple PMOS's can be used in combination to reduce power leakage within a digital circuit. For example, FIG. 4A is a diagram of a circuit 400 with two PMOS's 402, 404. In some implementations, the circuit can have more PMOS's. Using multiple PMOS's can reduce the power leakage by increasing the resistance of the circuit, e.g., by cutting off or super cutting off both PMOS's 402, 404. In some implementations, a same biasing voltage can be applied to the gates 406, 408 of both PMOS's 402, 404, respectively. For example, a biasing voltage Vₒₚₜ can be determined for the digital circuit that allows the least amount of current through the PMOS's. The biasing voltage Vₒₚₜ can be applied to both gates 406, 408. In another example, a biasing voltage equal to the input voltage V_{DD} of the digital circuit can be applied to both gates 406, 408. In some implementations, different biasing voltages can be applied to each of the gates 406, 408. In some implementations, both PMOS's 402, 404 can be super turned on by applying a negative biasing voltage to each of the gates 406, 408. In some implementations, the same negative biasing voltage can be applied to each of the gates 406, 408. In other implementations, different negative biasing voltages can be applied to each of the gates 406, 408.

Similarly, multiple NMOS's can be used in combination to reduce power leakage within a digital circuit. For example, FIG. 4B is a diagram of a circuit 450 with two NMOS's 452, 454. In some implementations, the circuit can have more NMOS's. Using multiple NMOS's can reduce the power leakage by increasing the resistance of the circuit, e.g., by cutting off or super cutting off both NMOS's 452, 454. In some implementations, a same biasing voltage can be applied to the gates 456, 458 of both NMOS's 452, 454, respectively to cut off or super cut off both NMOS's. For example, a desired negative biasing voltage can be determined, and the desired negative biasing voltage can be applied to both gates 456, 458 to super cut off the NMOS's. In some implementations, a biasing voltage equal to the input voltage V_{DD} of the digital circuit can be applied to both gates 456, 458 to turn on both NMOS's. In some implementations, both NMOS's 452, 454 can be super turned on by applying a positive biasing voltage greater than the V_{DD} to each of the gates 456, 458. For example, a biasing voltage Vₒₚₜ can be determined for the digital circuit that allows the least amount of current through the NMOS's. The biasing voltage Vₒₚₜ can be applied to both gates 456, 458. In some implementations, the same positive biasing voltage can be applied to each of the gates 456, 458. In other implementations, different positive biasing voltages can be applied to each of the gates 456, 458.

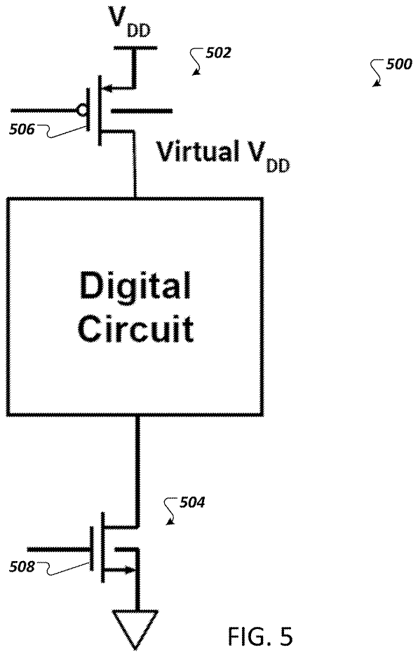

FIG. 5 illustrates a digital circuit 500 that includes a PMOS 502 and an NMOS 504. In some implementations, PMOS's and NMOS's can be used together in a digital circuit. In some implementations, the circuit 500 can have more or fewer PMOS's, and in some implementations the circuit 500 can have more or fewer NMOS's. Using both a PMOS and an NMOS can reduce the power leakage in the circuit, e.g., by cutting off both the NMOS and the PMOS. Also, power leakage can be reduced by super turning on both the NMOS and the PMOS.

In some implementations, using an NMOS and a PMOS can be more efficient than using two PMOS's or two NMOS's. For example, a negative biasing voltage (e.g., a biasing voltage below 0 volts) can be applied to the gate 506 of the PMOS 502 to super turn on the PMOS 502. A negative biasing voltage can be applied to the gate 508 of the NMOS 504 to super cut off the NMOS 504. The same negative biasing voltage can be used on either the PMOS 502 or the NMOS 504 depending on whether the circuit is on or off. This can be efficient, e.g., because a single negative voltage can be constantly generated and applied as a biasing voltage for either the PMOS 502 or the NMOS 504, depending on whether the circuit is on or off. Similarly, a positive biasing voltage can be applied to the gate 506 of the PMOS 502 to cut off or super cut off the PMOS 502. A positive biasing voltage can be applied to the gate 508 of the NMOS 504 to turn on or super turn on the NMOS 504. The same positive biasing voltage can be used on either the PMOS 502 or the NMOS 504, depending on whether the circuit is on or off. This can be efficient, e.g., because a single positive voltage can be constantly generated and applied as a biasing voltage for either the PMOS 502 or the NMOS 504, depending on whether the circuit is on or off. Constantly generating a negative biasing voltage and/or a positive biasing voltage and changing to which MOFSET, e.g., the PMOS or the NMOS, the biasing voltage is applied can be more efficient than generating a biasing voltage intermittently.

In some implementations, the negative biasing voltage applied to the gate 506 of the PMOS 502 to super turn on the PMOS 502 is different than the negative biasing voltage applied to the gate 508 of the NMOS 504 to super cut off the NMOS 504. Similarly, in some implementations, the positive biasing voltage applied to the gate 506 of the PMOS 502 to super cut off the PMOS 502 is different than the positive biasing voltage applied to the gate 508 of the NMOS 504 to super turn on the NMOS 504. In some implementations, a biasing voltage can be determined so that a desired amount of current flows through the PMOS when the biasing voltage is applied to the gate of the PMOS, and a desired amount of current flows through the NMOS when the biasing voltage is applied to the gate of the NMOS. In some implementations, the biasing voltage may not be the biasing voltage Vₒₚₜ that allows the least amount of current for either the PMOS or the NMOS. In some implementations, the positive biasing voltage applied to the gate 508 of the NMOS 504 to super turn on the NMOS 504 can have the same absolute value as the negative biasing voltage applied to the gate 508 of the NMOS 504 to super cut off the NMOS 504. In other implementations, the positive biasing voltage applied to the gate 508 of the NMOS 504 to super turn on the NMOS 504 has a different absolute value than the negative biasing voltage applied to the gate 508 of the NMOS 504 to super cut off the NMOS 504. Similarly, in some implementations, the positive biasing voltage applied to the gate 506 of the PMOS 502 to super cut off the PMOS 502 has the same absolute value as the negative biasing voltage applied to the gate 506 of the PMOS 502 to super turn on the PMOS 502. In other implementations, the positive biasing voltage applied to the gate 506 of the PMOS 502 to super cut off the PMOS 502 has a different absolute value than the negative biasing voltage applied to the gate 506 of the PMOS 502 to super turn on the PMOS 502.

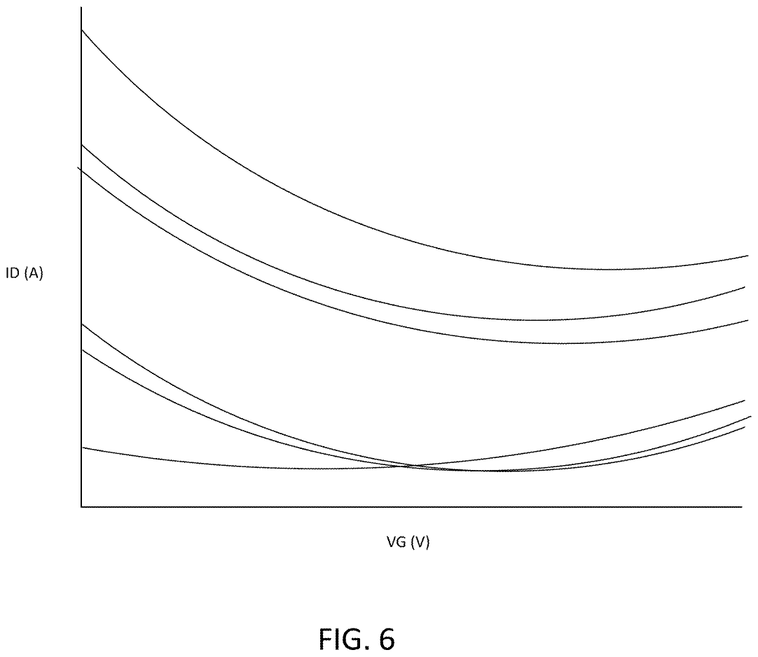

The desired biasing voltage for biasing a PMOS or NMOS can change depending on the digital circuits that are implemented. For example, process, voltage, and temperature (PVT) variations can change the current through a PMOS or NMOS. FIG. 6 is a plot illustrating applied biasing voltage vs. current in a number of PMOS's with different input voltages and attached to different circuits. As illustrated, the currents can change significantly depending on the PVT variations. In some implementations, these PVT variations can be accounted for during operation by a biasing circuit, which changes the applied biasing voltage according to feedback from the circuit.

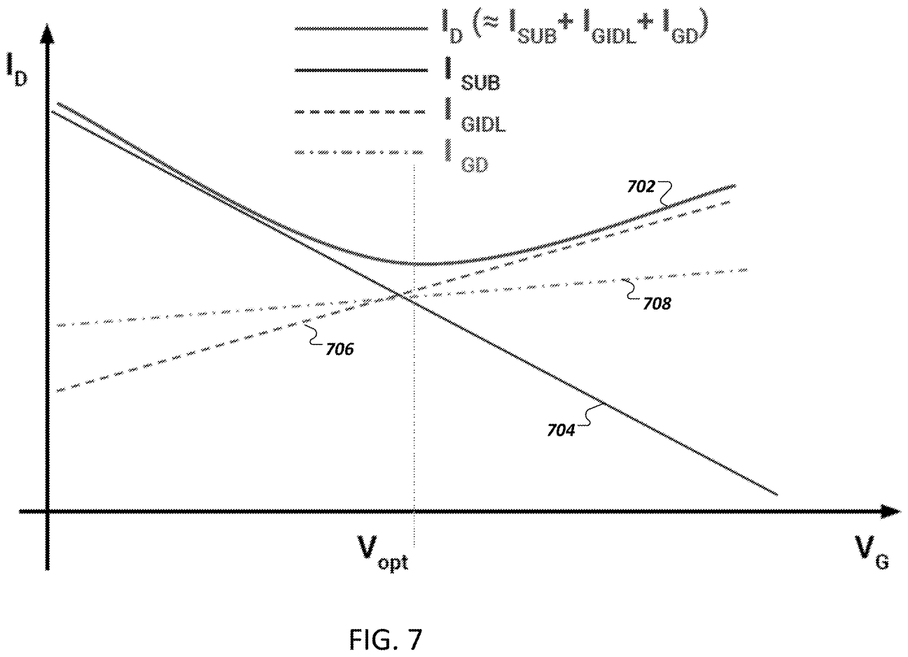

FIG. 7 illustrates applied voltage vs. current in a PMOS. In particular, FIG. 7 can be used to determine a biasing voltage to apply to a PMOS to get a desired current through the PMOS. FIG. 7 includes a curve 702 that is representative of the total current I_{D} through the PMOS. A first line 704 is representative of the subthreshold leakage current I_{SUB}. A second line 706 is representative of the gate induced drain leakage current I_{GIDL}. A third line 708 is indicative of the gate tunneling current between the gate and drain diffusion region I_{GD}. The curve 702 can be fit to the three lines 704, 706, 708 to determine the total current I_{D} at different applied voltages. In general, I_{D} is approximately equal to the sum of I_{SUB}, I_{GIDL}, and I_{GD}. Generally, the biasing voltage Vₒₚₜ at which the PMOS allows the least current can be reached when I_{SUB} is equal to the sum of I_{GIDL} and I_{GD}.

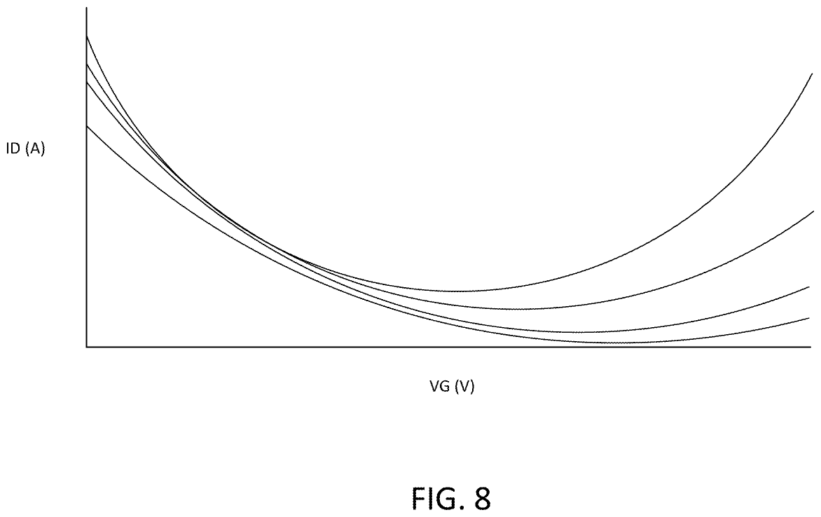

FIG. 8 illustrates applied biasing voltages vs. currents in a number of PMOS's. The PMOS's have different load voltages. As illustrated, the relationship between an applied voltage and a current in a PMOS changes depending on the load voltage. This further illustrates that currents can change significantly depending on PVT variations of a circuit. These PVT variations can be accounted for, e.g., by using a biasing circuit, receiving feedback from the circuit, changing the applied voltage, etc.

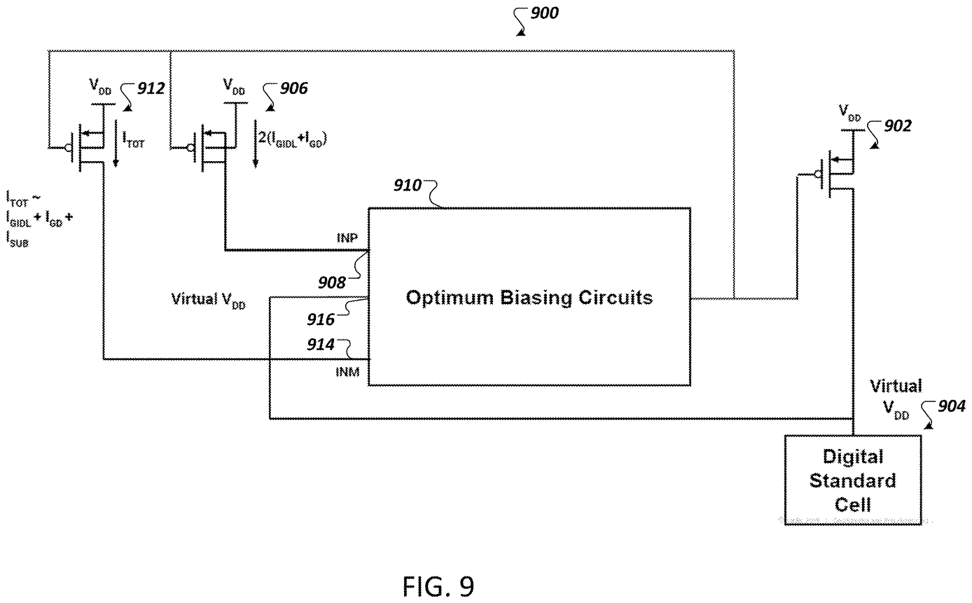

FIG. 9 illustrates an example logic circuit 900. The logic circuit 900 includes a first PMOS 902, which receives an input voltage V_{DD} and outputs a virtual V_{DD} to a digital cell 904, e.g., further circuitry. The circuit 900 also includes a second PMOS 906 that receives the same input voltage V_{DD} and outputs a voltage into a first input 908 of a biasing circuit 910. The current across the second PMOS 906 can be equal to two times the sum of I_{GIDL} and I_{GD}. The circuit 900 also includes a third PMOS 912 that receives the same input voltage V_{DD} and outputs a voltage into a second input 914 of the biasing circuit 910. The current across the third PMOS 912 can be equal to I_{D}. When the feedback circuit is stable, the sum of I_{GIDL} and I_{GD} will be equal to I_{SUB}.

The biasing circuit 910 can include, e.g., fully differential amplifiers, charge pumps, etc. The biasing circuit can also be implemented as a single ended biasing circuit, a switched-capacitor biasing circuit, a continuous time biasing circuit, etc. The biasing circuit 910 has a common mode input 916 that can receive a common mode voltage of the biasing circuit 910. The common mode input 916 is connected to the output of the first PMOS 902 and the digital cell 904, such that the common mode input 916 receives the same virtual V_{DD} as the digital cell. The biasing circuit receives the differential inputs 908, 914 and the common mode input 916 and outputs a single voltage, which is applied as a biasing voltage to the gates of each of the three PMOS's 902, 906, 912. Using the virtual V_{DD} as the common mode voltage provides a more consistent and accurate biasing circuit. This ensures that each of the PMOS's have the same biasing voltage applied. Simultaneous differential inputs from the first input 908 and the second input 912 and simultaneous common mode input 916 forces the voltage at each input to be equal. This provides a higher fidelity replica of the digital cell 904 and creates a circuit that will automatically adjust the applied biasing voltage, e.g., for PVT variations, across the circuit.

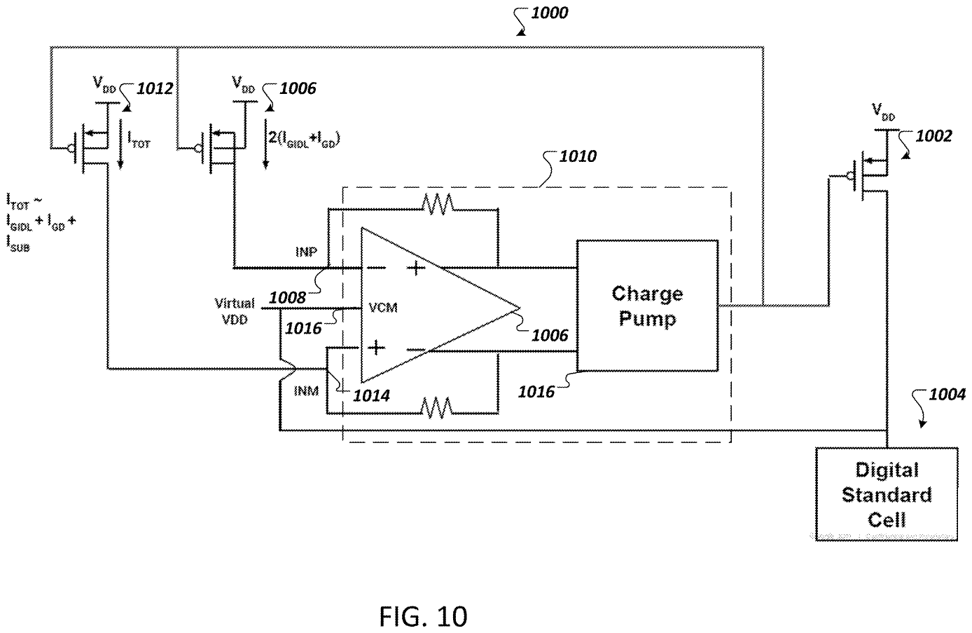

FIG. 10 illustrates another example logic circuit 1000. The logic circuit 1000 is similar to the logic circuit 900 of FIG. 9 and illustrates an exemplary biasing circuit. As discussed above, the biasing circuit can receive feedback and change the applied voltage to account for PVT variations. The logic circuit 1000 includes a first PMOS 1002, which receives an input voltage V_{DD} and outputs a virtual V_{DD} to a digital cell 1004, e.g., further circuitry. The circuit 1000 also includes a second PMOS 1006 that receives the same input voltage V_{DD} and outputs a voltage into a first input 1008 of a biasing circuit 1010. The current across the second PMOS 1006 can be equal to two times the sum of I_{GIDL} and I_{GD}. The circuit 1000 also includes a third PMOS 1012 that receives the same input voltage V_{DD} and outputs a voltage into a second input 1014 of the biasing circuit 1010. The current across the third PMOS 1012 can be equal to I_{D}.

The biasing circuit 1010 includes a fully differential amplifier 1018 and a charge pump 1020. The fully differential amplifier 1018 has a common mode input 1016 that can receive a common mode voltage. The fully differential amplifier 1018 receives the differential inputs 1008, 1014 and outputs differential voltage outputs to the charge pump 1020. The charge pump 1020 can receive the differential outputs from the fully differential amplifier 1018 and output a single voltage, which can be applied as a biasing voltage to the gates of each of the three PMOS's 1002, 1006, 1012. This ensures that each of the three PMOS's have the same biasing voltage. The common mode input 1016 is connected to the output of the first PMOS 1002 and the digital cell 1004, such that the common mode input 1016 receives the same virtual V_{DD} as the digital cell. Simultaneous differential inputs from the first input 1008 and the second input 1012 and simultaneous common mode input 1016 forces the voltage at each input to be equal. This provides a higher fidelity replica of the digital cell 904 and creates a circuit that will automatically adjust the applied biasing voltage, e.g., for PVT variations, across the circuit.

Although the exemplary logic circuits are depicted as including PMOS's, similar logic circuits can be created using NMOS's. For example, a biasing circuit can be configured to receive feedback as a common mode voltage and apply a negative biasing voltage to multiple NMOS's to automatically adjust the applied biasing voltage, e.g., for PVT variations, across the circuit.

Embodiments of the subject matter and the functional operations described in this specification can be implemented in digital electronic circuitry in computer hardware, including the structures disclosed in this specification and their structural equivalents, or in combinations of one or more of them. The processes and logic flows can also be performed by special purpose logic circuitry, e.g., an FPGA or an ASIC, or by a combination of special purpose logic circuitry and one or more programmed computers.

In addition to the embodiments described above, the following embodiments are also innovative:

Embodiment 1 is a logic circuit comprising:
a power source;
a biasing circuit;
a digital cell;
a first p-channel metal oxide semiconductor (PMOS) electrically connected between the power source and the digital cell;
a second PMOS electrically connected between the power source and a first input of the biasing circuit;
a third PMOS electrically connected between the power source and a second input of the biasing circuit;
wherein the digital cell is connected to a common mode voltage of the biasing circuit, such that the common mode voltage of the biasing circuit is substantially equal to a voltage received by the digital cell.

Embodiment 2 is the logic circuit of embodiment 1, wherein the biasing circuit comprises a fully differential amplifier, the fully differential amplifier configured to receive the first input, the second input, and the common mode voltage and configured to output differential voltages.

Embodiment 3 is the logic circuit of embodiment 1 or 2, wherein the biasing circuit comprises a charge pump configured to receive differential voltages and output a single voltage.

Embodiment 4 is the logic circuit of any one of embodiments 1-3, wherein the biasing circuit comprises a fully differential amplifier that is configured to receive the first input, the second input, and the common mode voltage and is configured to output differential voltages to a charge pump, the charge pump being configured to receive the differential voltages and output a single voltage.

Embodiment 5 is the logic circuit of any one of embodiments 1-4, wherein an output of the biasing circuit is configured to provide a positive biasing voltage to each PMOS.

Embodiment 6 is the logic circuit of any one of embodiments 1-5, wherein the voltage at the first input of the biasing circuit, the voltage at the second input of the biasing circuit, and the common mode voltage are substantially equal.

Embodiment 7 is a logic circuit comprising:
a power source;
a digital cell; and
a biasing circuit comprising:
   a first p-channel metal oxide semiconductor (PMOS) electrically connected between the power source and the digital cell;
   a second PMOS electrically connected between the power source and a first input of the biasing circuit;
   a third PMOS electrically connected between the power source and a second input of the biasing circuit;
wherein the digital cell is connected to a common mode voltage of the biasing circuit, such that the common mode voltage of the biasing circuit is substantially equal to a voltage received by the digital cell.

Embodiment 8 is the logic circuit of embodiment 7, wherein the biasing circuit comprises a fully differential amplifier, the fully differential amplifier configured to receive the first input, the second input, and the common mode voltage and output differential voltages.

Embodiment 9 is the logic circuit of embodiment 7 or 8, wherein the biasing circuit comprises a charge pump configured to receive differential voltages and output a single voltage.

Embodiment 10 is the logic circuit of any one of embodiments 7-9, wherein the biasing circuit comprises a fully differential amplifier that is configured to receive the first input, the second input, and the common mode voltage and output differential voltages to a charge pump, the charge pump being configured to receive the differential voltages and output a single voltage.

Embodiment 11 is the logic circuit of any one of embodiments 7-10, wherein an output of the biasing circuit is configured to provide a positive biasing voltage to each PMOS.

Embodiment 12 is the logic circuit of any one of embodiments 7-11, wherein the voltage at the first input of the biasing circuit, the voltage at the second input of the biasing circuit, and the common mode voltage are substantially equal.

Embodiment 13 is a method performed by a logic circuit comprising:
a power source,
a biasing circuit,
a digital cell,
a first p-channel metal oxide semiconductor (PMOS) electrically connected between the power source and the digital cell,
a second PMOS electrically connected between the power source and a first input of the biasing circuit, and
a third PMOS electrically connected between the power source and a second input of the biasing circuit, wherein the digital cell is connected to a common mode voltage of the biasing circuit,
the method comprising generating, by the logic circuit, a common mode voltage of the biasing circuit that is substantially equal to a voltage received by the digital cell.

Embodiment 14 is the method embodiment 13, wherein the biasing circuit comprises a fully differential amplifier, and further comprising receiving, by the fully differential amplifier, the first input, the second input, and the common mode voltage and outputting differential voltages.

Embodiment 15 is the method of any one of embodiments 13-14, wherein the biasing circuit comprises a charge pump configured to receive differential voltages and output a single voltage.

Embodiment 16 is the method of any one of embodiments 13-15, wherein the biasing circuit comprises a fully differential amplifier, and further comprising:
receiving, by the fully differential amplifier, the first input, the second input, and the common mode voltage and outputting differential voltages to a charge pump; and
receiving, by the charge pump, the differential voltages and outputting a single voltage.

Embodiment 17 is the method of any one of embodiments 13-16, wherein an output of the biasing circuit provides a positive biasing voltage to each PMOS.

Embodiment 18 is the method of any one of embodiments 13-17, wherein the voltage at the first input of the biasing circuit, the voltage at the second input of the biasing circuit, and the common mode voltage are substantially equal.

Embodiment 19 is a method performed by a logic circuit comprising:
a power source,
a digital cell, and
a biasing circuit comprising:
   a first p-channel metal oxide semiconductor (PMOS) electrically connected between the power source and the digital cell;
   a second PMOS electrically connected between the power source and a first input of the biasing circuit; and
   a third PMOS electrically connected between the power source and a second input of the biasing circuit;
wherein the digital cell is connected to a common mode voltage of the biasing circuit,
the method comprising generating, by the logic circuit, a common mode voltage of the biasing circuit that is substantially equal to a voltage received by the digital cell.

Embodiment 20 is the method of embodiment 19, wherein the biasing circuit comprises a fully differential amplifier, and further comprising receiving, by the fully differential amplifier, the first input, the second input, and the common mode voltage and outputting differential voltages.

Embodiment 21 is the method of any one of embodiments 19-20, wherein the biasing circuit comprises a charge pump and further comprising receive, by the charge pump, differential voltages and outputting a single voltage.

Embodiment 22 is the method of any one of embodiments 19-21, wherein the biasing circuit comprises a fully differential amplifier and further comprising:
receiving, by the fully differential amplifier, the first input, the second input, and the common mode voltage and outputting differential voltages to a charge pump; and
receiving, by the charge pump, the differential voltages and outputting a single voltage.

Embodiment 23 is the method of any one of embodiments 19-22, wherein an output of the biasing circuit provides a positive biasing voltage to each PMOS.

Embodiment 24 is the method of any one of embodiments 19-23, wherein the voltage at the first input of the biasing circuit, the voltage at the second input of the biasing circuit, and the common mode voltage are substantially equal.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In certain some cases, multitasking and parallel processing may be advantageous.

What is claimed is:

1. A logic circuit comprising:
a power source;
a biasing circuit;
a digital cell;
a first p-channel metal oxide semiconductor (PMOS) electrically connected between the power source and the digital cell;
a second PMOS electrically connected between the power source and a first input of the biasing circuit; and
a third PMOS electrically connected between the power source and a second input of the biasing circuit;
wherein the digital cell is connected to a common mode voltage of the biasing circuit, such that the common mode voltage of the biasing circuit is substantially equal to a voltage received by the digital cell.

2. The logic circuit of claim 1, wherein the biasing circuit comprises a fully differential amplifier, the fully differential amplifier configured to receive the first input, the second input, and the common mode voltage and configured to output differential voltages.

3. The logic circuit of claim 2, wherein the biasing circuit comprises a charge pump configured to receive differential voltages and output a single voltage.

4. The logic circuit of claim 3, wherein the biasing circuit comprises a fully differential amplifier that is configured to receive the first input, the second input, and the common mode voltage and is configured to output differential voltages to a charge pump, the charge pump being configured to receive the differential voltages and output a single voltage.

5. The logic circuit of claim 4, wherein an output of the biasing circuit is configured to provide a positive biasing voltage to each PMOS.

6. The logic circuit of claim 5, wherein the voltage at the first input of the biasing circuit, the voltage at the second input of the biasing circuit, and the common mode voltage are substantially equal.

7. A logic circuit comprising:
a power source;
a digital cell; and
a biasing circuit comprising:
a first p-channel metal oxide semiconductor (PMOS) electrically connected between the power source and the digital cell;
a second PMOS electrically connected between the power source and a first input of the biasing circuit; and
a third PMOS electrically connected between the power source and a second input of the biasing circuit;
wherein the digital cell is connected to a common mode voltage of the biasing circuit, such that the common mode voltage of the biasing circuit is substantially equal to a voltage received by the digital cell.

8. The logic circuit of claim 7, wherein the biasing circuit comprises a fully differential amplifier, the fully differential amplifier configured to receive the first input, the second input, and the common mode voltage and output differential voltages.

9. The logic circuit of claim 8, wherein the biasing circuit comprises a charge pump configured to receive differential voltages and output a single voltage.

10. The logic circuit of claim 9, wherein the biasing circuit comprises a fully differential amplifier that is configured to receive the first input, the second input, and the common mode voltage and output differential voltages to a charge pump, the charge pump being configured to receive the differential voltages and output a single voltage.

11. The logic circuit of claim 10, wherein an output of the biasing circuit is configured to provide a positive biasing voltage to each PMOS.

12. The logic circuit of claim 11, wherein the voltage at the first input of the biasing circuit, the voltage at the second input of the biasing circuit, and the common mode voltage are substantially equal.

13. A method performed by a logic circuit comprising:
a power source,
a biasing circuit,
a digital cell,
a first p-channel metal oxide semiconductor (PMOS) electrically connected between the power source and the digital cell,
a second PMOS electrically connected between the power source and a first input of the biasing circuit, and
a third PMOS electrically connected between the power source and a second input of the biasing circuit, wherein the digital cell is connected to a common mode voltage of the biasing circuit,
the method comprising generating, by the logic circuit, a common mode voltage of the biasing circuit that is substantially equal to a voltage received by the digital cell.

14. The method claim 13, wherein the biasing circuit comprises a fully differential amplifier, and further comprising receiving, by the fully differential amplifier, the first input, the second input, and the common mode voltage and outputting differential voltages.

15. The method of claim 14, wherein the biasing circuit comprises a charge pump configured to receive differential voltages and output a single voltage.

16. The method of claim 15, wherein the biasing circuit comprises a fully differential amplifier, and further comprising:
receiving, by the fully differential amplifier, the first input, the second input, and the common mode voltage and outputting differential voltages to a charge pump; and
receiving, by the charge pump, the differential voltages and outputting a single voltage.

17. The method of claim 16, wherein an output of the biasing circuit provides a positive biasing voltage to each PMOS.

18. The method of claim 17, wherein the voltage at the first input of the biasing circuit, the voltage at the second input of the biasing circuit, and the common mode voltage are substantially equal.

19. A method performed by a logic circuit comprising:
a power source,
a digital cell, and
a biasing circuit comprising:
a first p-channel metal oxide semiconductor (PMOS) electrically connected between the power source and the digital cell;
a second PMOS electrically connected between the power source and a first input of the biasing circuit; and
a third PMOS electrically connected between the power source and a second input of the biasing circuit;
wherein the digital cell is connected to a common mode voltage of the biasing circuit,
the method comprising generating, by the logic circuit, a common mode voltage of the biasing circuit that is substantially equal to a voltage received by the digital cell.

20. The method of claim 19, wherein the biasing circuit comprises a fully differential amplifier, and further comprising receiving, by the fully differential amplifier, the first input, the second input, and the common mode voltage and outputting differential voltages.

21. The method of claim 19, wherein the biasing circuit comprises a charge pump and further comprising receive, by the charge pump, differential voltages and outputting a single voltage.

22. The method of claim 21, wherein the biasing circuit comprises a fully differential amplifier and further comprising:
receiving, by the fully differential amplifier, the first input, the second input, and the common mode voltage and outputting differential voltages to a charge pump; and
receiving, by the charge pump, the differential voltages and outputting a single voltage.

23. The method of claim 22, wherein an output of the biasing circuit provides a positive biasing voltage to each PMOS.

24. The method of claim 23, wherein the voltage at the first input of the biasing circuit, the voltage at the second input of the biasing circuit, and the common mode voltage are substantially equal.
